(19) United States
(12) Patent Application Publication
(10) Pub. No.: US 2024/0032213 A1
(43) Pub. Date: Jan. 25, 2024

(54) DEVICE FOR ESTABLISHING AN INTERLOCK CONNECTION

(71) Applicant: Brose Fahrzeugteile SE & Co. Kommanditgesellschaft, Würzburg, Würzburg (DE)

(72) Inventors: Markus Rauch, Bamberg (DE); Marko Wisner, Kirchdorf an der Iller (DE)

(21) Appl. No.: 18/479,362

(22) Filed: Oct. 2, 2023

Related U.S. Application Data
(63) Continuation of application No. PCT/EP2022/058205, filed on Mar. 29, 2022.

(30) Foreign Application Priority Data
Mar. 30, 2021 (DE) 10 2021 203 197.8

(51) Int. Cl. H05K 5/02; H01R 13/46; H01R 31/08; H01R 13/73

(52) U.S. Cl. CPC H05K 5/0208; H01R 13/46; H01R 31/08; H01R 13/73; H01R 2201/26

(57) ABSTRACT

A device for establishing an interlock connection contains a plug assembly and a circuit carrier. The plug assembly has two plug terminals with in each case at least one associated interlock contact. A structural element for mechanical reinforcement of the circuit carrier is arranged on the circuit carrier. The structural element is a pot-shaped housing part, and the structural element has a contact element for electrically contacting the interlock contacts.

### CROSS-REFERENCE TO RELATED APPLICATION

This application is a continuation, under 35 U.S.C. § 120, of copending International Patent Application PCT/EP2022/058205, filed Mar. 29, 2022, which designated the United States; this application also claims the priority, under 35 U.S.C. § 119, of German Patent Application DE 10 2021 203 197.8, filed Mar. 30, 2021; the prior applications are herewith incorporated by reference in their entireties.

### FIELD AND BACKGROUND OF THE INVENTION

The invention relates to a device for establishing an interlock connection.

In motor vehicles, air-conditioning systems are regularly fitted which air-condition the interior of the vehicle with the aid of a system forming a refrigerant circuit. In essence, systems of this type have a circuit in which a refrigerant is carried. The refrigerant, for example R-134a (1,1,1,2-tetrafluoroethane) or R-744 (carbon dioxide), is heated in an evaporator and compressed by means of a (refrigerant) compressor, wherein the refrigerant subsequently discharges the absorbed heat via a heat exchanger before being carried to the evaporator once again via an orifice tube.

In applications of this type, it is possible in principle to use scroll units for example as compressors for the refrigerant. Scroll compressors of this type typically have two scroll parts which can be moved relative to each other and which operate in the manner of a positive displacement pump. The two scroll parts are typically configured as an interleaved pair of (helical) spirals or scrolls. In other words, one of the spirals engages at least in part with the other spiral. The first (scroll) spiral is fixed in place relative to a compressor housing (stationary scroll, fixed scroll), wherein the second (scroll) spiral (movable scroll, orbiting scroll) is driven in an orbiting manner within the first spiral by means of an electric motor.

An electric motor, in particular a brushless electric motor, serving as an electric (three-phase) machine, conventionally has a stator which is provided with a multi-phase field or stator winding and is arranged coaxially with a rotor comprising one or more permanent magnets. Both the rotor and the stator are constructed, for example, as lamination stacks, wherein stator teeth bear the coils of the stator winding in stator grooves located therebetween.

In a brushless electric motor, the alternating current provided to power the stator winding is conventionally generated by a converter (inverter). In the case of relatively small electric motors, this converter is frequently received together with associated control electronics, serving as the motor electronics, in an electronics housing which is integrated for example as an electronics compartment in a motor housing. The motor electronics are attached to a vehicle power supply system via an attachment region of the electronics housing by a plug connecting means.

The electrical refrigerant drive is generally a high-voltage component, which means that the refrigerant drive is and/or the motor electronics are attached to a high DC voltage, for example greater than or equal to 60 V (volts), in particular 470 V. Accordingly, a high voltage is carried through the plug connection by the plug connecting means.

If the plug connecting means or the contact with the inverter of the motor electronics is disconnected, it may not be possible for the electrical energy stored in the inverter and/or the energy in an attached vehicle battery to be reduced in time or safely. For general personal protection purposes and to avoid damage, an electrical safety lock is therefore generally provided for the high-voltage plug connecting means which connects to the motor electronics.

In the case of an electrical (safety) lock of this type, also known as an interlock or high-voltage interlock (HV interlock), the correct connection of plug connections of the power supply system is monitored in order to avoid contact being disconnected unintentionally, inappropriately or for any other reason while the power supply system is active. For this purpose, a pilot or safety line for example is provided, which is routed from plug connection to plug connection as a series connection (AND operation). For example, a low-voltage or lock signal, also referred to as an interlock signal, which loops via the plug connecting means through each component attached to the power supply system, is fed into the safety line.

If one of the attached plug connecting means is released or the contact thereof is disconnected, the entire loop is opened due to the resulting disconnection of the pilot contacts in the plug connecting means. The status or interlock signal is monitored by a control device which, in the event of a fault status, in which contact is interrupted, switches off the power supply system of the vehicle for example.

For this purpose, further interlock contacts are arranged in the device plugs in addition to the electrical (high-voltage) connectors, which interlock contacts close a circuit with the control device when the device plug is plugged in. This control device ultimately switches the (high-voltage) potential to the load. It is therefore necessary to establish a connection between the interlock contacts within the device plug and the control device. The potential level of the control device is in this case relatively low (for example 12 V power supply system in the vehicle).

To ensure suitable distances are provided for air gaps and creepage paths, it is necessary for the interlock circuit and the HV circuit to be routed at a sufficient distance from each other. However, the distances required increase the surface area required on a printed circuit board assembly if the circuit is closed thereon.

From German patent. DE 10 2019 111 691 B4 (corresponding to U.S. patent publication No. 2022/0052496), an arrangement for plug connecting electrical connections through a housing is known, in which the arrangement has a first plug connection having first plug connecting means and a second plug connection having second plug connecting means for transmitting electrical energy in independent transmitting ranges, and a receiving element for receiving plug connecting means. In this case, the receiving element having the first plug connecting means and the second plug connecting means is implemented as an integral and cohesive unit and one-piece component. The arrangement also has an interlock connection which is configured as an electrical lock and is electrically conductively connected to the plug connecting means of the plug connections.

### SUMMARY OF THE INVENTION

The invention is based on the object of specifying a particularly suitable device for establishing an interlock connection. The invention is further based on the object of specifying a particularly suitable contact element.

With regard to the device, the object is achieved according to the invention by the features of the independent claim. Advantageous configurations and developments form the subject matter of the dependent claims.

The device according to the invention is provided for establishing an interlock connection, i.e., for establishing an electrical (safety) lock connection, and is suitable and adapted for this purpose. The device has a plug assembly serving as a plug connecting means or device plug, and a circuit carrier. The circuit carrier is configured, for example, as a printed circuit board or printed circuit board assembly. It is also conceivable for the circuit carrier to take the form of a lead frame for example, in particular an overmolded lead frame. The following explanations relate in particular to a printed circuit board serving as a circuit carrier, wherein the explanations can also, however, apply analogously to other circuit carriers.

The plug assembly has two plug connectors, each containing at least one associated interlock contact. A pot-shaped housing part is arranged on the circuit carrier as a structural element which mechanically reinforces or stabilizes the circuit carrier. The structural element has a contact element for establishing electrical contact with the interlock contacts. In other words, the interlock connection is achieved by means of the contact element of the structural element. This achieves a particularly suitable device for establishing an interlock connection.

The contact element can be arranged on an outer side of the structural element. However, it is also possible to arrange the contact element internally or to integrate it into the structural element itself, for example by overmolding the contact element with the structural element.

Preferably, the plug assembly has a high-voltage connector comprising high-voltage plug contacts and at least one high-voltage interlock contact, and a low-voltage connector containing low-voltage plug contacts and at least one low-voltage interlock contact. The high-voltage plug contacts and low-voltage plug contacts, and the at least one high-voltage interlock contact and the at least one low-voltage interlock contact are embedded in a common housing of the plug assembly and protrude via the free ends thereof from the housing. In other words, the plug assembly is preferably configured as an integral or one-piece assembly.

Mating contacts for the high-voltage and low-voltage plug contacts are provided on the circuit carrier in a suitable manner. In a preferred embodiment, the structural element is configured as a housing-shaped or pot-shaped cover or cap which covers the mating contacts. For example, the structural element is configured as a plastics material cap. Feed through openings for the high-voltage and low-voltage plug contacts are expediently introduced in the structural element. This means that the mating contacts are arranged within the structural element, wherein, for example, the contact element is arranged on an outer side of the structural element remote from the circuit carrier. Contact between the high-voltage and low-voltage plug contacts and the mating contacts is therefore preferably established inside the structural element, and the interlock connection is established for example outside the structural element. This means that the distances for air gaps and creepage paths are achieved by means of the structural element and are not required on the circuit carrier.

The invention provides that the required connection between the interlock contacts of the plug assembly and a control unit is established via a suitable structural element which has contacts and electrical conductors. In contrast with the interlock connection configuration in a plug assembly according to the prior art, the interlock connection is established by means of the structural element and/or by means of the contact element. The advantage of this is that uniform plug assemblies can be used, and it is not necessary to establish the interlock connection on the electronics layout or the circuit carrier. Product-specific adaptation is achieved by routing the conductors in a suitable manner in the structural element.

Suitable constructional measures, such as insulating the conductors in the structural element and selecting a suitable material for the structural element, such as a non-tracking plastics material, make it possible to miniaturize the structural element.

The structural element can optionally be joined to the circuit carrier in a form-fitting, force-fitting or materially bonded manner. The structural element can in this case fulfil further functions, for example routing the plug contacts for tolerance compensation, reinforcing the circuit carrier and supporting large electrical components. The structural element can also serve solely to establish the interlock connection.

A “form fit” or “form-fitting connection” between at least two interconnected parts is understood here and in the following to mean in particular that the cohesion between the interconnected parts, at least in one direction, is achieved by direct meshing of the contours of the parts themselves or by indirect meshing via an additional connecting part. The form thus “blocks” any mutual movement in this direction.

A “force fit” or “force-fitting connection” between at least two interconnected parts is understood here and in the following to mean in particular that the interconnected parts are prevented from sliding against one another due to a frictional force acting between them. If a “connecting force” (meaning the force which presses the parts against one another, for example a bolt force or the force of gravity itself) which gives rise to this frictional force is absent, the force-fitting connection cannot be maintained and is therefore released.

A “material bond” or “materially bonded connection” between at least two interconnected parts is understood here and in the following in particular to mean that the interconnected parts are held together at the contact faces thereof by material bonding or cross-linking (for example due to atomic or molecular binding forces), where appropriate under the effect of an additive.

The contact element can be configured as a separate component. In other words, the contact element can be configured so as to be separate from the plug assembly and from the structural element.

In an expedient implementation, the contact element is fastened to the structural element, in particular in a releasable or replaceable manner. This makes it possible to adapt the structural element in a particularly simple and flexible manner to differing conductor or contact arrangements in a plug assembly.

In a possible embodiment, the contact element is fastened, for example clamped, latched or locked, to the structural element in a form-fitting and/or force-fitting manner. In this way, the contact element can be fastened in a simple and reliable manner. The conjunction “and/or” is to be understood here and in the following in such a way that the features linked by this conjunction can be implemented both together and as alternatives to one another.

An additional or further aspect of the invention provides that the contact element has at least one electrical conductor for establishing electrical contact with the interlock contacts, which conductor is embedded, in portions, in a body made of an electrically non-conductive material. In other words, the conductor is integrated at least in part in an insulating body, wherein the free end of the conductor projects from the body and is or can be contacted by the interlock contacts. The conductor is for example a bent part, in particular a punched-bent part. The body is for example a plastics material body, in particular in the form of an injection-molded part which surrounds the conductor, serving as an insert, in portions. The body is for example produced from a non-tracking plastics material. This achieves a simple and cost-effective contact element.

In an alternative configuration, the contact element does not have an insulating body, and the conductors can therefore be individually laid and fastened in a suitable manner (for example by overmolding or by means of a clip fastening) in or on the structural element.

In a preferred embodiment, the body has at least one fastening element, which is integrally formed i.e., formed in one piece or monolithically, for mechanical fastening to the structural element. As a result, no additional fastening means, such as screws, are required to fasten the contact element to the structural element.

In a conceivable implementation, the fastening element is configured in particular to lock with the structural element in the manner of a mushroom-head fastener. For example, the fastening element is configured as a press fastener with a mushroom-head-shaped cross section, which is pressed into a socket or cavity of the structural element and engages behind it in a form-fitting manner. The press fastener is formed, for example, by a plurality of circumferentially arranged press tabs. This makes it possible to fasten the contact element in a particularly simple manner.

In an advantageous further development, the portion of the conductor embedded in the body has an offset, in particular a step-shaped offset, which is oriented transversely to a longitudinal direction extending between the interlock contacts. This further development is particularly advantageous if the connectors of the plug assembly have an offset. In terms of construction, an offset of this type in the conductors is obtained through an advantageous configuration optimized for the punch-bending of the conductors themselves. This ensures that the contact faces of the conductors are always routed in parallel to the respective contacts or connectors of the plug assembly. If the contact faces are formed on the conductors by punch-bending, a right-angled bend relative to the longitudinal direction of the conductor is advantageous. The offset in the plane between the interlock connectors of the plug assembly is thus compensated by an offset in the conductor routing. However, it is not necessary in this case for the offset in the conductors to be right-angled or for the offset to be implemented in the insulating body described. If the contact faces are formed using a different technology, for example by welding on a contact element, it is possible, where appropriate, to dispense with the offset transverse to the longitudinal direction.

In a conceivable configuration, a portion of the conductor extending between the body and the interlock contact, in particular the low-voltage interlock contact, has an axial offset in an axial direction oriented perpendicularly to the circuit carrier surface. The axial offset is routed in a suitable manner along a housing wall of the structural element. As a result, the conductors follow the contour of the structural element. The structural element is advantageously formed in such a way that it surrounds the underlying components in a conformal manner so as to be able to perform further functions such as providing support. In addition, the axial offset in the structural element makes it possible to align the plug connectors or contacts of the plug assembly in a chronologically offset manner, which achieves improved tolerance compensation and can be better monitored from a process technology perspective.

The offsets in the longitudinal and/or axial direction are predetermined, for example, by the constructional parameters of the plug assembly and make it possible to compensate for tolerances. The conductors can, however, also be implemented without an offset.

Contact between the plug assembly and the interlock connection on the structural element can be established for example via plug, pressure, pin/socket, lamella or insulation displacement contacts, or another electrical connection. In a preferred embodiment, the free ends of the conductor are implemented as clip or spring contacts which, in the contacted state, rest against the interlock contacts in a resilient manner.

In a suitable configuration, the interlock contacts of the plug assembly and/or the free ends of the conductor engage in openings in the structural element. This means that the interlock connection or contact is established in the interior of the structural element so that the contact points are protected from external influences. It is also possible for example to transfer the interlock connection to the circuit carrier.

Other features which are considered as characteristic for the invention are set forth in the appended claims.

Although the invention is illustrated and described herein as embodied in a device for establishing an interlock connection, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a diagrammatic, perspective view of a first embodiment of a device for establishing an interlock connection, having a plug assembly and a printed circuit board containing a structural element according to the invention;

FIG. 2 is a perspective view of the interlock connection;

FIG. 3 is a perspective view of the interlock connection without the printed circuit board and the structural element;

FIG. 4 is a side view of the interlock connection;

FIG. 5 is a perspective view of a contact element;

FIG. 6 is a plan view of the contact element;

FIG. 7 is a side view of the contact element;

FIG. 8 is a perspective view of a second embodiment of the device; and

FIG. 9 is a perspective view of the device according to FIG. 8.

### DETAILED DESCRIPTION OF THE INVENTION

Like parts and dimensions are consistently denoted with like reference signs in all figures.

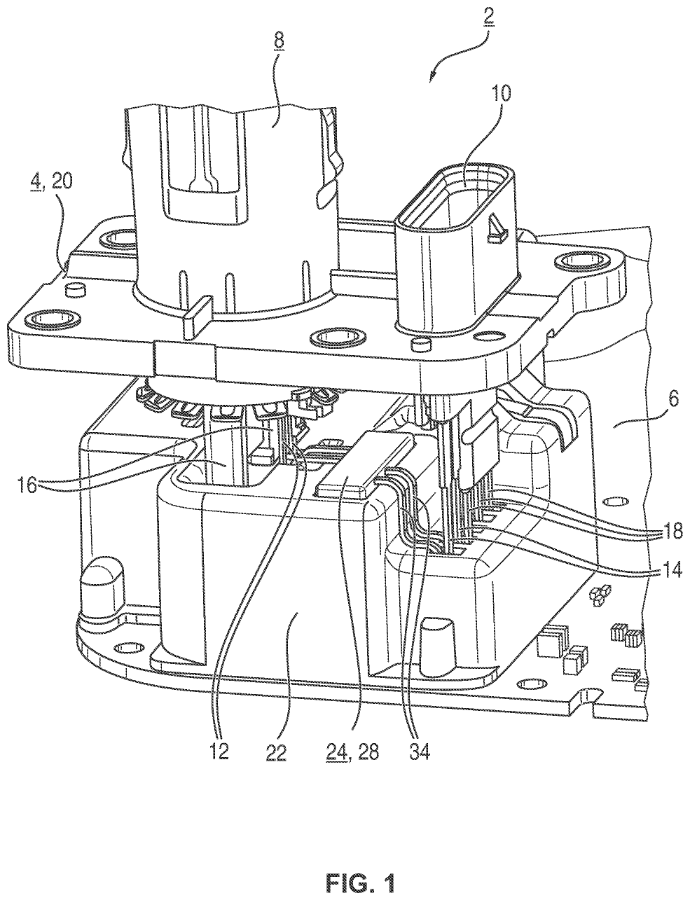

Referring now to the figures of the drawings in detail and first, particularly to FIG. 1 thereof, there is shown a device 2 for establishing an interlock connection. The device 2 for example forms part of an electrical refrigerant compressor of a motor vehicle. The device 2 has a plug assembly 4 and a circuit carrier 6. The circuit carrier 6 is configured as a printed circuit board (PCB) and is also referred to as such below.

The plug assembly 4 is configured as a plug connection or device plug of the refrigerant drive. The plug assembly 4 has two plug connectors 8, each of which has two associated interlock contacts 12, 14.

The plug connector 8 is configured as a high-voltage connector, i.e., as a connector for a high-voltage connection, in particular for voltages above 60 V, in particular 470 V. The plug connector 8 has two plug contacts 16 (high-voltage plus, high-voltage minus) and two (high-voltage) interlock contacts 12.

The plug connector 10 is configured as a low-voltage connector, i.e., as a connector for a low-voltage connection, in particular for voltages below 60 V, in particular 12 V. The plug connector 10 has three plug contacts 18 and two (low-voltage) interlock contacts 14. Two of the plug contacts 18 are contacted or can be contacted by a vehicle battery (KL30, KL31) and one of the plug contacts 18 is routed to a communication line (COM).

The plug contacts 16, 18 and the interlock contacts 12, 14 are embedded in a common housing or overmolding 20 of the plug assembly 4, and protrude, via the free ends thereof, from the latter in the direction of the printed circuit board 6. The plug assembly 4 is preferably configured as an integral or one-piece assembly; in particular the plug assembly 4 forms a common high-voltage-low-voltage plug (HV-LV plug).

Mating contacts (not shown in greater detail) for the plug contacts 16, 18 are arranged on the printed circuit board 6. Arranged on the printed circuit board 6 is a pot-shaped or cap-shaped housing part, serving as a structural element 22, which mechanically reinforces or stabilizes the printed circuit board 6 at least locally and covers the mating contacts. The structural element 22 is configured for example as a plastics material cap, for example in the form of an injection-molded part made of a non-tracking plastics material. In this embodiment, the structural element 22 is fastened by means of screws to the printed circuit board 6. The structural element 22 is mounted in a corner region of the printed circuit board 6 as shown in FIG. 1.

A contact element 24 is mounted on the outer side of the structural element 22 facing the plug assembly 4. The contact element 24 establishes the electrical connection between the interlock contacts 16, 18 and thus forms the interlock connection.

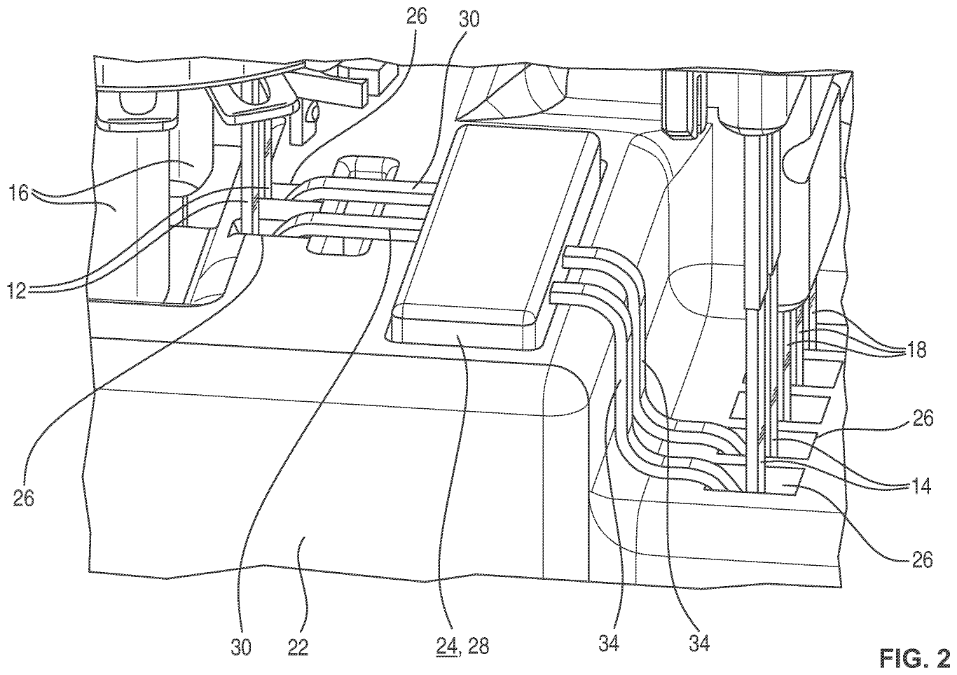

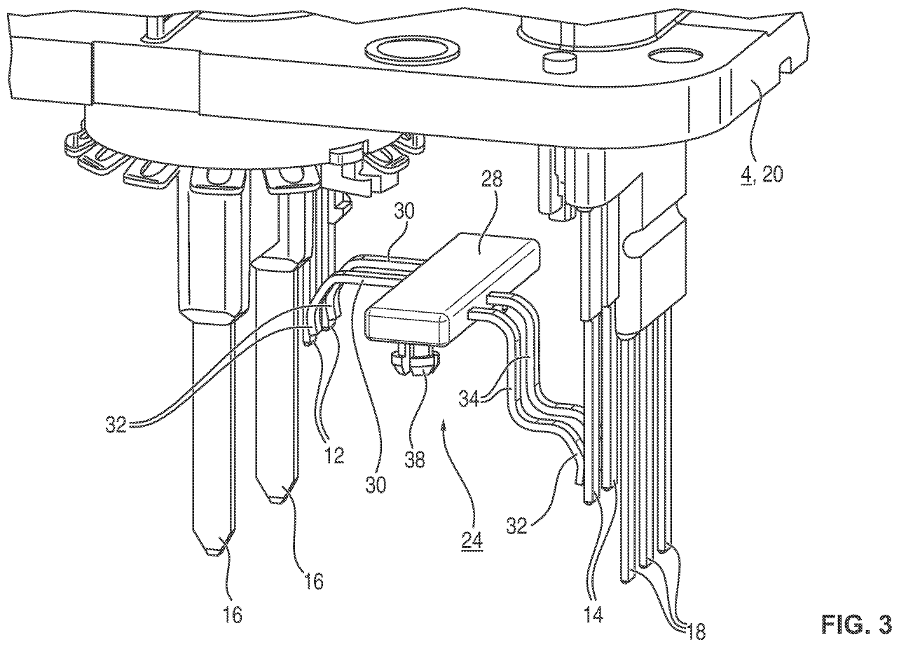

The interlock connection established by means of the contact element 24 is shown in greater detail in FIGS. 2 to 4. The contact element 24 is shown individually in FIGS. 5 to 7.

On the side facing the plug assembly 4, the structural element 22 has recesses or (feedthrough) openings 26 for receiving the interlock contacts 12, 14. In the interlock state, the interlock contacts 12, 14 thus extend, at least in portions, into the structural element 22. In an alternative embodiment, the interlock contacts 12, 14 project for example from the structural element 22.

In this embodiment, the contact element 24 is configured as a separate component which can be releasably or replaceably fastened in a force-fitting and/or form-fitting manner in a socket (not specified in greater detail) of the structural element 22.

The contact element 24 is configured so as to be optimized for assembly and is specifically formed for establishing galvanic contact with the interlock contacts 12, 14. For this purpose, the contact element 24 has an approximately cuboid-shaped body 28 from which two electrical conductors 30 project. The conductors 30 are routed parallel to and at a distance from each other and, at the free ends 32 thereof, are each contacted by an interlock contact 12, 14.

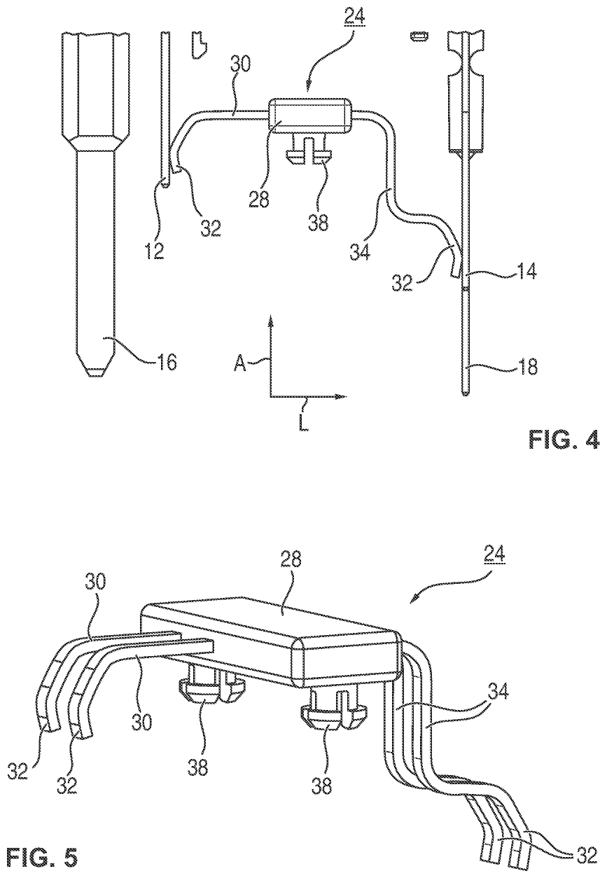

The conductors 30 are configured for example as punched-bent parts, for example as lead frames, which are embedded or integrated at least in portions into the body 28. As shown for example in FIGS. 4 and 7, the free ends 32 are curved convexly inward relative to the interlock contacts 12, 14 and in the direction of the printed circuit board 6, and thus form clip or spring contacts which, in particular in the outer apex region of the curve, rest in a resilient manner against the respectively associated interlock contacts 12, 14. As shown in FIG. 2 for example, the free ends 32, together with the interlock contacts 12, 14, engage in the openings 26 of the structural element 22.

The portion of the conductors 30 projecting from the body 28 in the direction of the interlock contacts 14 has a step-shaped axial offset 34 in the direction of the printed circuit board 6. The offset 34 extends parallel to an axial direction A oriented perpendicularly to the printed circuit board 6. As shown in particular in FIG. 2, the conductor 30 is thus routed along a step-shaped axial offset of the structural element 22.

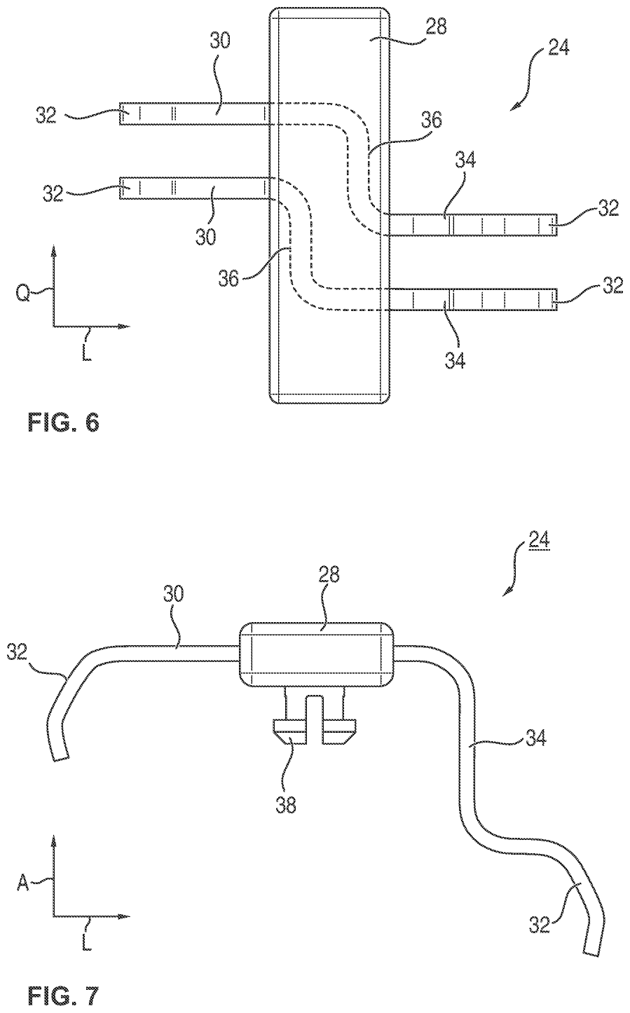

As shown in particular in FIG. 6, the conductors 30 have a further step-shaped offset 36 within the body 30. The offset 36 is oriented transversely to a longitudinal direction L extending between the interlock contacts 12, 14. The offset 36 is in particular oriented parallel to a transverse direction Q which is oriented perpendicularly to the longitudinal direction L and the axial direction A.

The body 28 is for example a plastics material body, in particular in the form of an injection-molded part, which surrounds the conductor 30, serving as an insert, in portions, in particular in the region of the offset 36. The body 28 is for example produced from an electrically insulating, in particular non-tracking, plastics material.

On an underside facing the structural element 22, the body 28 has two fastening elements 38, which are integrally formed, i.e., formed in one piece or monolithically, for fastening to the structural element 22 in a form-fitting and/or force-fitting manner. The two fastening elements 38 are arranged at a distance from each other, so that it is possible to fasten the contact element 24 in a stable and non-rotational manner.

The fastening elements 38 are configured in particular to lock with the structural element 22 in the manner of a mushroom-head fastener. In the embodiment shown, the fastening elements 38 are configured as press fasteners with a mushroom-head-shaped cross section, which are pressed into a socket or cavity of the structural element 22 and engage behind it in a form-fitting manner. The fastening elements 38 are each formed by a plurality of circumferentially arranged press tabs which can be bent radially inward and each of which have a catch projection at the free end thereof.

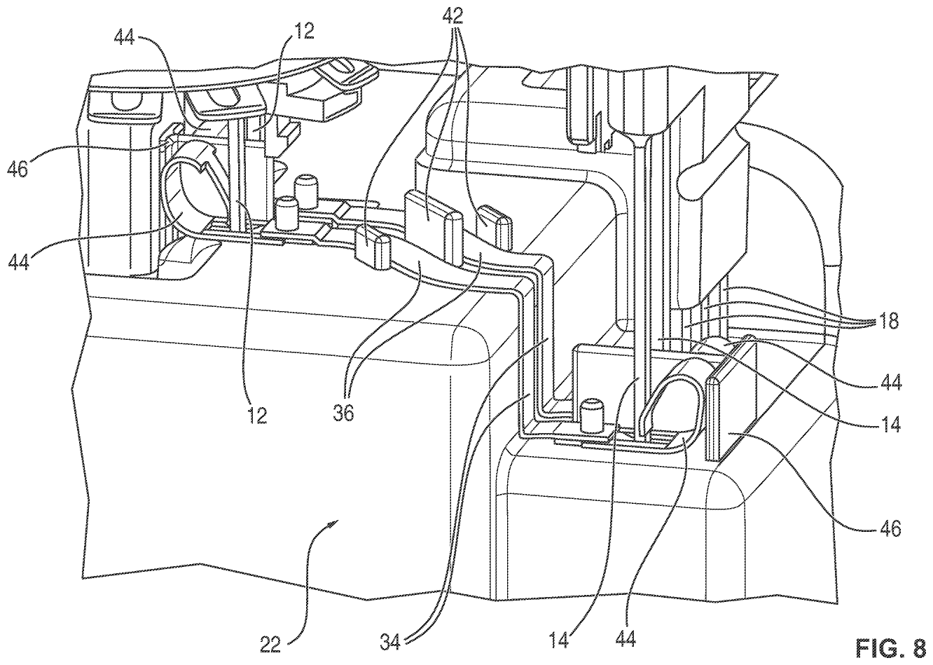

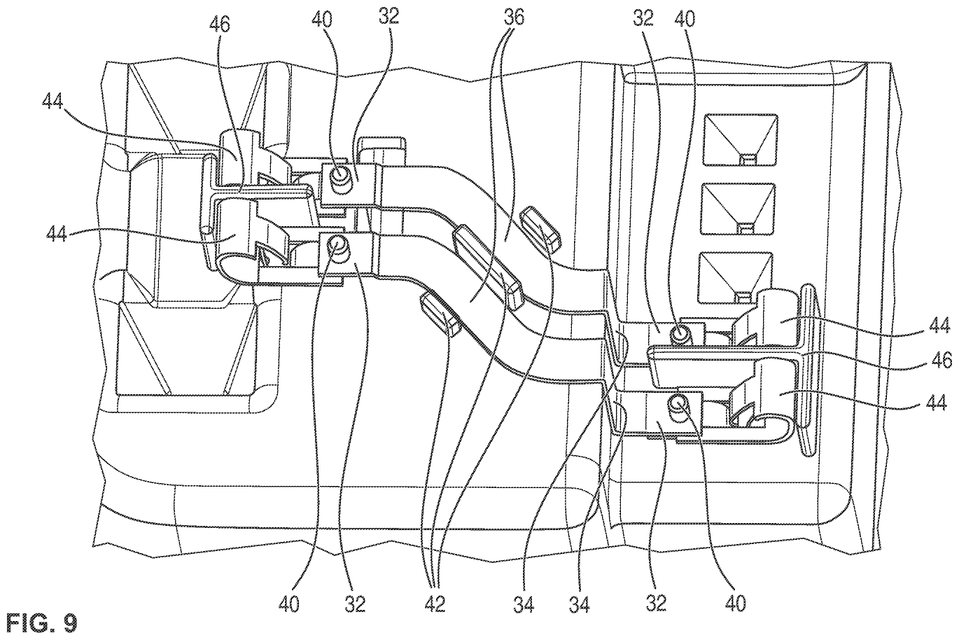

A second exemplary embodiment of the device 2 is explained in greater detail below with reference to FIGS. 8 and 9. The exemplary embodiment in FIGS. 8 and 9 differs from the exemplary embodiment in FIGS. 1 to 7 described above, in particular with regard to the configurations of the interlock connection and the contact element 24.

In this embodiment, the contact element 24 does not have an (insulating) body 28. The conductors 30 are configured in particular as punched-bent conductor paths which are routed on an outer side of the structural element 22. The conductors 30 are laid individually for example and fastened to the structural element 22. In the exemplary embodiment shown, the tab-shaped free ends 32 each have an opening (not specified in greater detail), which is joined in each case to a protruding joining extension 40 of the structural element 22.

The offset 36 is configured to be approximately S-shaped rather than right-angled. The structural element 22 has three guide walls 42 which are arranged parallel to one another, which protrude perpendicularly from the outer side, and between which the conductors 36 are routed in the region of the offset 36.

The free ends 32 are each electrically conductively connected to a contact end 44 in the region of the joining extensions 40. The contact ends 44 do not engage with the structural element 22 and are arranged substantially completely outside the structural element 22. The contact ends 44 have a slot toward the free ends 32, in which the interlock contacts 12, 14 fit in the (interlock) contacted state. A contact blade adjoining the slot is bent in the manner of a clip contact toward the interlock contacts 12, 14 or in the direction of the free ends 32 and, in the contacted state, preferably rests in a resilient manner against the interlock contacts 12, 14 (FIG. 8).

To support and stabilize the contact blades of the contact ends 44, two support walls 46, which are approximately T-shaped in cross-section, are integrally formed on the structural element 22. The contact ends 44 are each supported on the horizontal T-branch of the support wall 46, wherein the vertical T-branch extends along the contact ends 44 up to the linking point with the free ends 32.

The invention is not limited to the exemplary embodiments described above. Rather, other variants of the invention can also be derived therefrom by a person skilled in the art within the scope of the disclosed claims without departing from the subject matter of the invention. Furthermore, in particular, all the individual features described in connection with the exemplary embodiments can also be otherwise combined with one another within the scope of the disclosed claims without departing from the subject matter of the invention.

The following is a summary list of reference numerals and the corresponding structure used in the above description of the invention:
2 device
4 plug assembly
6 circuit carrier/printed circuit board
8 plug connector
10 plug connector
12 interlock contact
14 interlock contact
16 plug contact
18 plug contact
20 overmolding
22 structural element
24 contact element
26 opening
28 body
30 conductor
32 free end
34 offset
36 offset
38 fastening element
40 joining extension
42 guide wall
44 contact end
46 support wall
A axial direction
L longitudinal direction
Q transverse direction

1. A device for establishing an interlock connection, the device comprising:
a plug assembly having two plug connectors each with at least one associated interlock contact;
a circuit carrier;
a structural element for mechanically reinforcing said circuit carrier disposed on said circuit carrier, said structural element is a pot-shaped housing part; and
a contact element for establishing electrical contact with associated interlock contacts.

2. The device according to claim 1, wherein said the contact element is fastened to said structural element.

3. The device according to claim 1, wherein said contact element is fastened to said structural element in a form-fitting and/or force-fitting manner.

4. The device according to claim 1, wherein said contact element has at least one electrical conductor for establishing electrical contact with said associated interlock contacts, and a body made of an electrically non-conductive material, said at least one electrical conductor is embedded, in portions, in said body.

5. The device according to claim 4, wherein said body has at least one integrally formed fastening element for mechanical fastening to said structural element.

6. The device according to claim 5, wherein said at least one integrally formed fastening element is configured to lock with said structural element in a manner of a mushroom-head fastener.

7. The device according to claim 4, wherein said at least one electrical conductor has an offset which is oriented transversely to a longitudinal direction extending between said associated interlock contacts and disposed in an embedded portion.

8. The device according to claim 4, wherein a portion of said at least one electrical conductor extending between said body and one of said interlock contacts has an axial offset in an axial direction oriented perpendicularly to a circuit carrier surface.

9. The device according to claim 4, wherein said at least one electrical conductor has free ends implemented as clip contacts.

10. The device according to claim 9, wherein:
said structural element has openings formed therein; and
said interlock contacts of said plug assembly and/or said free ends of said at least one electrical conductor engage in said openings of said structural element.
